(19) United States
(12) Patent Application Publication
(10) Pub. No.: US 2020/0352024 A1
(43) Pub. Date: Nov. 5, 2020

(54) STRUCTURE AND WIRING SUBSTRATE

(71) Applicant: NEC CORPORATION, Tokyo (JP)

(72) Inventor: Yoshiaki KASAHARA, Tokyo (JP)

(73) Assignee: NEC Corporation, Tokyo (JP)

(21) Appl. No.: 16/099,214

(22) PCT Filed: May 8, 2017
(86) PCT No.: PCT/JP2017/017416

§ 371 Date: Nov. 6, 2018

(30) Foreign Application Priority Data
May 11, 2016 (JP) 2016-094958

(51) Int. Cl. H05K 1/02; H05K 1/11

(52) U.S. Cl. CPC H05K 1/0236; H05K 2201/093; H05K 1/115

(57) ABSTRACT

The present invention solves the problem that propagation of electromagnetic noise in a predetermined frequency band cannot be suppressed when an existing EBG structure is applied in a multilayer substrate. The structure of the present invention is provided with: a first power plane; a first GND plane faces the first power plane; a second GND plane faces the first power plane or the first GND plane; a first planar conductor facing the first GND plane and/or the second GND plane; a first conductor via for connecting the first planar conductor and the first power plane, the first conductor via being insulated from the first GND plane and the second GND plane; and a second conductor via for connecting the first GND plane and the second GND plane, the second conductor via being insulated from the first power plane and the first planar conductor.

### TECHNICAL FIELD

The present invention relates to a structure and a wiring substrate and, in particular, to a structure and a wiring substrate that suppress electromagnetic noise.

### BACKGROUND ART

In an electronic device in which a plurality of conductor planes exist, the conductor planes serve as waveguides through which an electromagnetic wave propagates. An electromagnetic wave is generated by induction of a magnetic field due to electric current flowing into a circuit when a digital circuit is switched or by induction of an electric field due to a voltage variation which occurs during switching. The electromagnetic wave thus generated becomes electromagnetic noise which propagates through parallel plate wave guides formed by conductor planes and leads to problems such as destabilization of operations of other circuits and degradation of radio performance of a device. Therefore, if a technique that suppresses electromagnetic noise can be established, stability of circuits and radio performance of devices can be improved.

Techniques related to the present invention that suppress electromagnetic noise in high-frequency bands (for example, a 2.4 GHz band, a 5.2 GHz band, and a 5.6 GHz band used in wireless Local Area Networks (LANs) and a 1.8 GHz band, a 2.6 GHz band, and a 3.5 GHz band used in Long Term Evolution (LTE)) are described in PTLs 1 to 4. Structures described in PTLs 1 to 4 include a structure having electromagnetic band gap (EBG) characteristics (hereinafter referred to as EBG structure). EBG characteristics are dispersive characteristics having a bandgap forbidding propagation in a particular frequency band in which no electromagnetic wave propagation mode exists. The structures described in PTLs 1 to 4 can suppress propagation of electromagnetic noise generated between a power plane and a ground (GND) plane which are parallel plate wave guides. By designing an EBG structure in such a way that EBG characteristics are exhibited in a GHz band, electromagnetic noise in the GHz band being a high-frequency band can be suppressed. PTL 2 discloses that a structure of the related technique can be applied to a multilayer substrate that includes a plurality of pairs of a power plane and a GND plane.

### CITATION LIST

### Patent Literature

[PTL 1] U.S. Pat. No. 7,215,007 Description
[PTL 2] Japanese Patent Publication No. 4862163
[PTL 3] Japanese Unexamined Patent Application Publication No.

2010-199881
[PTL 4] Japanese Unexamined Patent Application Publication No. 2010-10183
[PTL 5] Re-publication of PCT International Publication No. 2009/145237 Description

### SUMMARY OF INVENTION

### Technical Problem

However, when an existing EBG structure is used in a multilayer substrate that includes a plurality of pairs of a power plane and a GND plane in practice, the EBG characteristics cannot be obtained at a predetermined frequency (i.e., a characteristic frequency) in spite of the fact that the multilayer substrate has the EBG structure. In other words, a multilayer substrate that uses an existing EBG structure cannot suppress electromagnetic noise in a predetermined frequency band. In order to suppress electromagnetic noise in a predetermined frequency band in a multilayer substrate, an EBG structure needs to be redesigned. However, changing design of an EBG structure is not easy because electromagnetic noise propagating in a multilayer substrate has a plurality of propagation paths.

An object of the present invention is to provide a structure and a wiring substrate that can suppress propagation of electromagnetic noise in a predetermined frequency band without changing design of an existing EBG structure when the existing EBG structure is applied to a multilayer substrate including a plurality of pairs of a power plane and a GND plane.

### Solution to the Problem

A structure according to the present invention includes: a first conductor plane that is a power plane; a second conductor plane that is a GND plane and faces the first conductor plane; a third conductor plane that is a GND plane and faces the first conductor plane or the second conductor plane; a first planar conductor that faces at least one of the second conductor plane and the third conductor plane; a first conductor via that connects the first planar conductor and the first conductor plane, and is insulated from the second conductor plane and the third conductor plane; and a second conductor via that connects the second conductor plane and the third conductor plane, and is insulated from the first conductor plane and the first planar conductor.

A wiring substrate according to the present invention includes: a first conductor plane that is a power plane; a second conductor plane that is a GND plane and faces the first conductor plane; a third conductor plane that is a GND plane and faces the first conductor plane or the second conductor plane; a first planar conductor that faces at least one of the second conductor plane and the third conductor plane; a first conductor via that connects the first planar conductor and the first conductor plane, and is insulated from the second conductor plane and the third conductor plane; and a second conductor via that connects the second conductor plane and the third conductor plane, and is insulated from the first conductor plane and the first planar conductor.

### Advantageous Effects of Invention

An advantageous effect of the present invention is that, when an existing EBG structure is applied to a multilayer substrate including a plurality of pairs of a power plane and a GND plane, propagation of electromagnetic noise in a predetermined frequency band can be suppressed without changing design of the existing EBG structure.

### BRIEF DESCRIPTION OF DRAWINGS

FIG. 1 is perspective views illustrating configurations of a structure 1 according to a first example embodiment of the present invention;

FIG. 2 is cross-sectional views illustrating configurations of the structure 1 according to the first example embodiment of the present invention;

FIG. 3 is cross-sectional views illustrating configurations of the structure 1 according to the first example embodiment of the present invention;

FIG. 4 is a configuration diagram illustrating a configuration of a wiring substrate 10 according to the first example embodiment of the present invention;

FIG. 5 is a top view illustrating a configuration of a variation of the wiring substrate 10 according to the first example embodiment of the present invention;

FIG. 6 is a perspective view illustrating a configuration of a structure 2 according to a first variation of the first example embodiment of the present invention;

FIG. 7 is a cross-sectional view illustrating the configuration of the structure 2 according to the first variation of the first example embodiment of the present invention;

FIG. 8 is a cross-sectional view illustrating the configuration of the structure 2 according to the first variation of the first example embodiment of the present invention;

FIG. 9 is a perspective view illustrating a configuration of a structure 2 according to a second variation of the first example embodiment of the present invention;

FIG. 10 is a top view illustrating a configuration of a wiring substrate 20 according to a second example embodiment of the present invention;

FIG. 11 is a perspective view illustrating a configuration of a structure 3 according to a third example embodiment of the present invention;

FIG. 12 is a cross-sectional view illustrating the configuration of the structure 3 according to the third example embodiment of the present invention;

FIG. 13 is a cross-sectional view illustrating the configuration of the structure 3 according to the third example embodiment of the present invention; and

FIG. 14 is a top view illustrating a configuration of a wiring substrate 30 according to a fourth example embodiment of the present invention.

### EXAMPLE EMBODIMENT

In the technical field of the present invention, there have been studied methods for suppressing electromagnetic noise propagating through parallel plate wave guides formed by conductor planes, such as a method that inserts a decupling capacitor between conductor planes. The method using a decupling capacitor is limited to application to frequencies up to about several hundred Mhz. In other words, the method cannot be applied to high-frequency bands as used in radio communication in recent years.

Example embodiments for carrying out the present invention will be described below in detail with reference to drawings. Note that like reference symbols are given to components that include like functions in the example embodiments illustrated in drawings and the description.

### First Example Embodiment

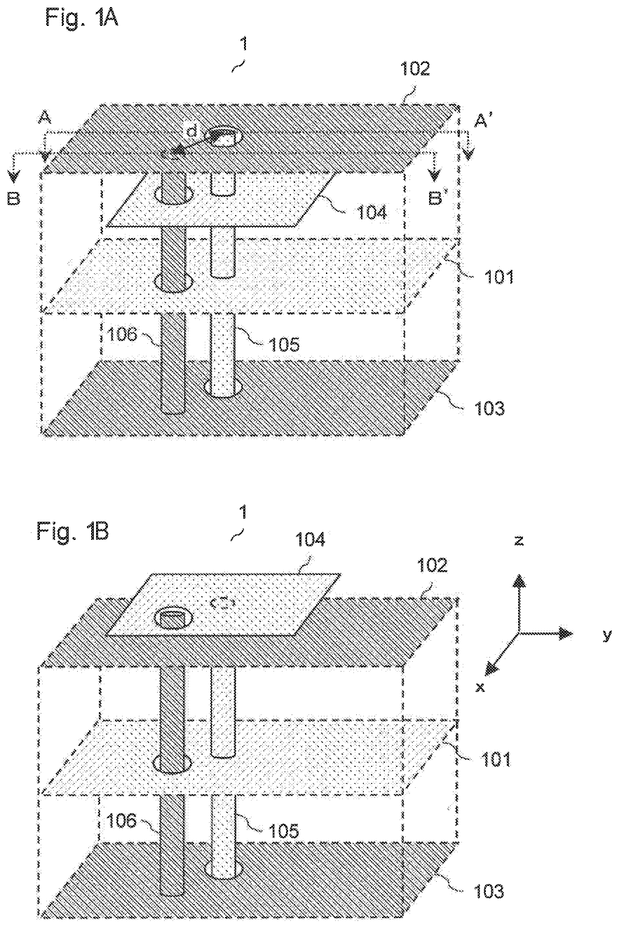

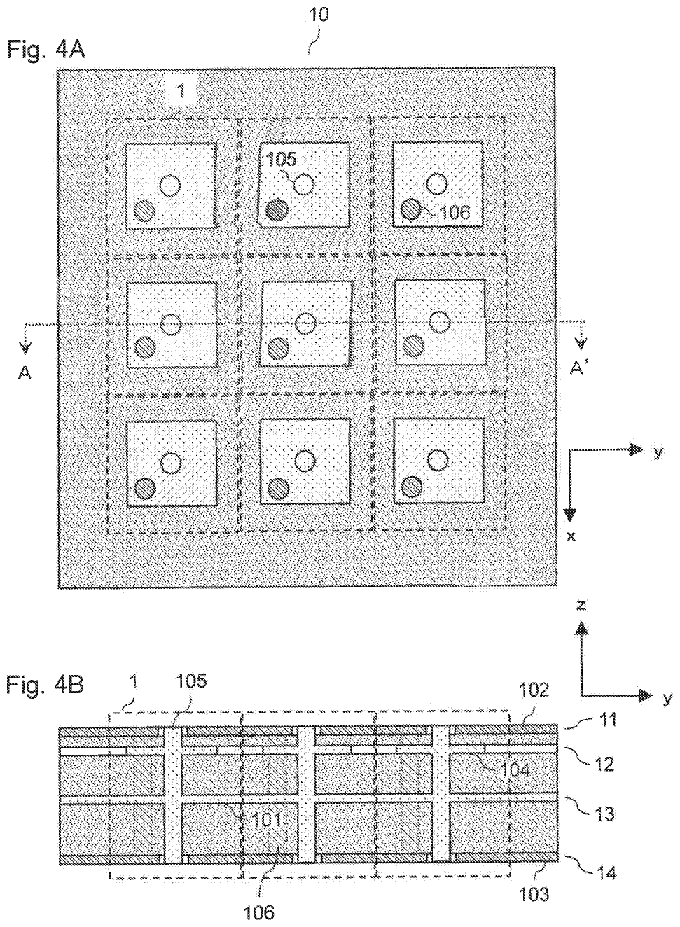

FIG. 1 is perspective views illustrating configurations of a structure 1 according to a first example embodiment of the present invention. The structure 1 is made up of various conductive components formed in a wiring substrate 10 (see FIG. 4) including at least a layer K 11, a layer L 12, a layer M 13, and a layer N 14. The layer K 11, the layer L 12, the layer M 13, and the layer N 14 are configured in layers that are substantially parallel to each other and different from each other and are layered in this order.

Referring to FIG. 1, the structure 1 according to the first example embodiment of the present invention includes a first conductor plane 101, a second conductor plane 102, a third conductor plane 103, a first planar conductor 104, a first conductor via 105, and a second conductor via 106. Each of the first conductor plane 101, the second conductor plane 102, the third conductor plane 103, and the first planar conductor 104 is formed in any one of the layer K 11, the layer L 12, the layer M 13, and the layer N 14 of the wiring substrate 10. In the present example embodiment, the second conductor plane 102 is formed in the layer K 11, the first planar conductor 104 is formed in the layer L 12, the first conductor plane 101 is formed in the layer M 13, and the third conductor plane 103 is formed in the layer N 14. However, the positional relationship among the first conductor plane 101, the second conductor plane 102, the third conductor plane 103, and the first planar conductor 104 is not limited to this.

The structure 1 according to the first example embodiment can suppress propagation of electromagnetic noise generated between the first conductor plane 101 and the second conductor plane 102 and between the first conductor plane 101 and the third conductor plane 103 by an EBG structure and the second conductor via 106, which will be describe later.

The EBG structure is made up of the first conductor plane 101, the second conductor plane 102, the first planar conductor 104 and the first conductor via 105. The EBG structure can suppress propagation of electromagnetic noise generated between parallel plate wave guides made up of the first conductor plane 101 that is a power plane and the second conductor plane 102 that is a GND plane.

Since the structure 1 according to the first example embodiment includes the second conductor via 106, propagation of electromagnetic noise in a predetermined frequency band can be suppressed without changing design of an existing EBG structure in the case where the existing EBG structure is applied to a multilayer substrate (i.e., in the case where the third conductor plane 103 that is a GND plane is further provided in the existing EBG).

Components provided in the first structure 1 according to the first example embodiment will be described below.

The first conductor plane 101, the second conductor plane 102, and the third conductor plane 103 are flat plates each extending in a plane that is parallel to an xy plane of a coordinate system illustrated in FIG. 1 and facing each other. In other words, the first conductor plane 101, the second conductor plane 102, and the third conductor plane 103 are formed in layers that are different from each other. The first conductor plane 101 faces the second conductor plane 102 on one surface (in the z-axis positive direction of the coordinate system illustrated in FIG. 1) and faces the third conductor plane 103 on the other surface (in the z-axis negative direction of the coordinate system illustrated in FIG. 1). It is envisaged that in an actual electronic device, the first conductor plane 101 is a power plane, and the second conductor plane and the third conductor plane are GND planes.

The first planar conductor 104 is a flat plate formed in a plane that is parallel to the xy plane of the coordinate system illustrated in FIG. 1 and in a layer different from the layers in which the first conductor plane 101, the second conductor plane 102, and the third conductor plane 103 are formed. The first planar conductor 104 faces one of the second conductor plane 102 and the third conductor plane 103. While it is desirable that no other conductor exist between the first planar conductor 104 and any one of the second conductor plane 102 and the third conductor plane 103 that faces the first planar conductor 104, another conductor may exist there.

In the present example embodiment and other example embodiments, the first planar conductor 104 faces the second conductor plane 102 without another conductor between the first planar conductor 104 and the second conductor plane 102.

The first conductor via 105 extends in the z-axis direction of the coordinate system illustrated in FIG. 1 and passes through the first conductor plane 101, the second conductor plane 102, the third conductor plane 103, and the first planar conductor 104. The first conductor via 105 galvanically connects the first conductor plane 101 and the first planar conductor 104 together. The first conductor via 105 is insulated from the second conductor plane 102 and the third conductor plane 103 by clearances formed in the second conductor plane 102 and the third conductor plane 103. In other words, the first conductor via 105 passes through the clearances formed in the second conductor plane 102 and the third conductor plane 103. The clearance herein means an opening.

In the present example embodiment, the clearance formed in the second conductor plane 102 and the first planar conductor 104 face each other without another conductor between them. The clearance formed in the third conductor plane 103 and the first conductor plane 101 face each other without another conductor between them. In FIG. 1, the clearances formed in the second conductor plane 102 and the third conductor plane 103 are circular in shape. However, the shape of the clearances formed in the second conductor plane 102 and the third conductor plane 103 is not specifically limited, as long as the clearances allow the first conductor via 105 to pass through.

The second conductor via 106 extends in the z-axis direction of the coordinate system illustrated in FIG. 1 and passes through the first conductor plane 101, the second conductor plane 102, the third conductor plane 103, and the first planar conductor 104. The second conductor via 106 galvanically connects the second conductor plane 102 and the third conductor plane 103 together. The second conductor via 106 is insulated from the first conductor plane 101 and the first planar conductor 104 by clearances formed in the first conductor plane 101 and the first planar conductor 104. In other words, the second conductor via 106 passes through the clearances formed in the first conductor plane 101 and the first planar conductor 104.

In the present example embodiment, the clearance formed in the first conductor plane 101 and the third conductor plane 103 face each other without another conductor between them. The clearance formed in the first planar conductor 104 and the second conductor plane 102 face each other without another conductor between them. In FIG. 1, the clearances formed in the first conductor plane 101 and the first planar conductor 104 are circular in shape. However, the shape of the clearances formed in the first conductor plane 101 and the first planar conductor 104 is not specifically limited, as long as the clearances allow the second conductor via 106 to pass through.

It is desirable that the distance d between the second conductor via 106 and the first conductor via 105 be small. For example, it is desirable that d be equal to or less than ½ of λg (d≤λg/2), where λg is a guide wavelength at an operating frequency of the EBG structure. For example, the distance d between the second conductor via 106 and the first conductor via 105 may be equal to or less than ¼ (d≤λg/4). The guide wavelength λg herein means a wavelength that takes into account the relative permittivity of a dielectric.

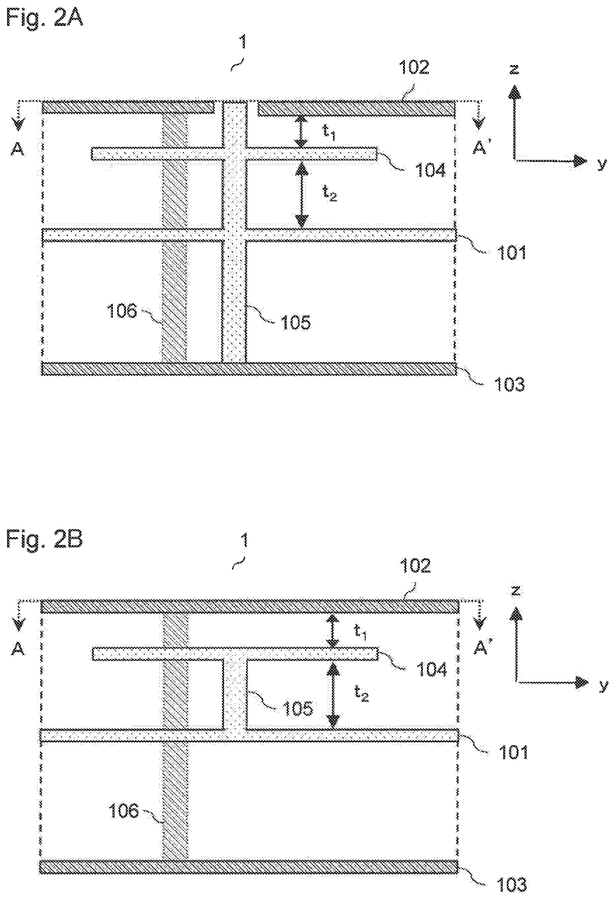

FIG. 2 illustrates an A-A′ cross-sectional view of the structure 1 illustrated in FIG. 1(A) and a diagram of a variation thereof. It is desirable that the distance t1 between the first planar conductor 104 and the second conductor plane 102 be smaller than the distance t2 between the first planar conductor 104 and the first conductor plane 101. For example, the distance t1 between the first planar conductor 104 and the second conductor plane 102 may be one half of the distance t2 between the first planar conductor 104 and the first conductor plane 101 (t1=t2/2).

In the first example embodiment, the structure 1 can suppress propagation of electromagnetic noise in a predetermined frequency band without changing design of an existing EBG structure in the case where the existing EBG structure is applied to a multilayer substrate (i.e., in the case where the third conductor plane 103 that is a GND plane is further provided in the existing EBG structure).

In the present example embodiment, the first planar conductor 104 is provided between the first conductor plane 101 and the second conductor plane 102 as illustrated in FIG. 1(A). However, the first planar conductor 104 may be provided in such a way as to face the surface opposite to the surface of the second conductor plane 102 that faces the first conductor plane 101 as illustrated in FIG. 1(B).

While the first planar conductor 104 in the present example embodiment is configured in a square shape smaller in area than the first conductor plane 101, the second conductor plane 102, and the third conductor plane 103, the first planar conductor 104 may be configured in another shape. For example, the first planar conductor 104 may be configured in a polygonal shape such as another quadrilateral shape, a triangular shape, or a hexagonal shape, a circular shape, or a star shape, or may be configured larger in area than the first conductor plane 101, the second conductor plane 102, and the third conductor plane 103.

In the present example embodiment, the first conductor via 105 passes through the first conductor plane 101, the second conductor plane 102, the third conductor plane 103, and the first planar conductor 104 as illustrated in FIG. 2(A). However, the configuration of the first conductor via 105 is not limited to this. For example, as illustrated in FIG. 2(B), the first conductor via 105 does not need to extend to an extent to pass through the second conductor plane 102 and the third conductor plane 103. In other words, there may be at least one of a conductor plane and a planar conductor through which the first conductor via 105 does not completely pass through, as long as the first conductor via 105 can galvanically connect the first conductor plane 101 and the first planar conductor 104 together. A clearance does not need to be provided in at least one of the second conductor plane and the third conductor plane through which the first conductor via 105 does not pass.

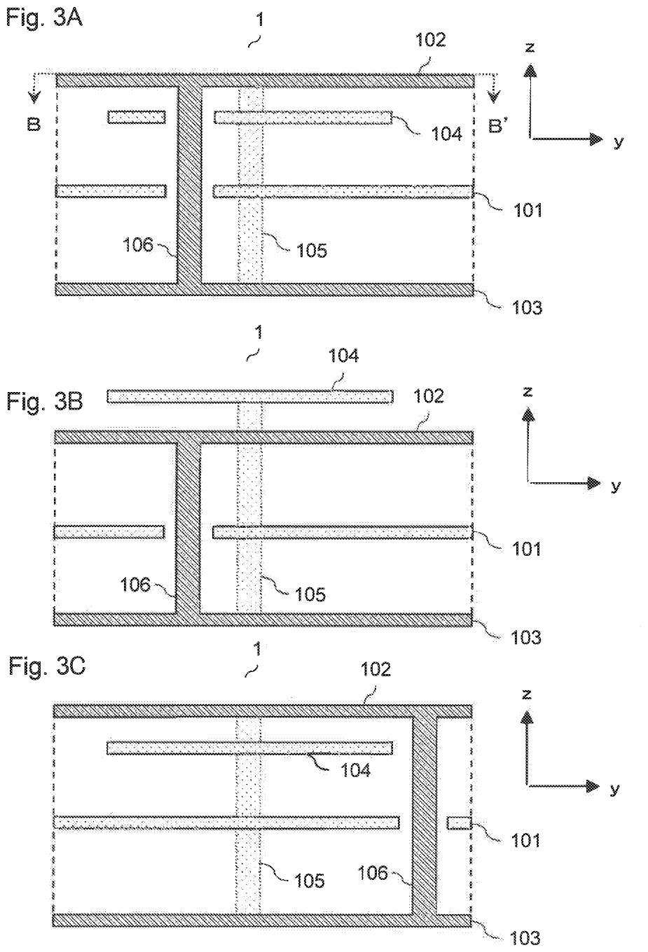

FIG. 3 is a B-B′ cross-sectional view of the structure 1 illustrated in FIG. 1(A) and a diagram of a variation thereof.

In the present example embodiment, the second conductor via 106 passes through the first conductor plane 101, the second conductor plane 102, the third conductor plane 103, and the first planar conductor 104 as illustrated in FIG. 3(A). However, the configuration of the second conductor via 106 is not limited to this. For example, in the case where the first planar conductor 104 is provided in such a way as to face the surface opposite to the surface of the second conductor plane 102 that faces the surface of the second conductor plane 102 that faces the first conductor plane 101 (see FIG. 1(B)), the second conductor via 106 does not need to extend to pass through the first planar conductor 104, as illustrated in FIG. 3(B). In other words, there may be one of a conductor plane and a planar conductor through which the second conductor via 106 does not completely pass through, as long as the second conductor via 106 can galvanically connect the second conductor plane 102 and the third conductor plane 103 together. A clearance does not need to be provided in the first planar conductor 104 through which the second conductor via 106 does not pass.

Further, as illustrated in FIG. 3(C), the second conductor via 106 may be provided outside the region in which the first planar conductor 104 exists in planar view (as viewed from the z-axis direction), as long as the distance d between the second conductor via 106 and the first conductor via 105 is equal to or less than ½ of λg (d≤λg/2), (more desirably equal to or less than ¼ (d≤λg/4))).

In the present example embodiment, the structure 1 may include a layer other than the layer K 11, the layer L 12, the layer M 13, and the layer N 14 described above. For example, as illustrated in FIG. 4, the structure 1 may include a dielectric layer between the layer K 11 and the layer L 12, between the layer L 12 and the layer M 13, and between the layer M 13 and the layer N 14. The structure 1 may further include at least one other conductor layer used as a power plane or a GND plane. A conductor layer used as a GND plane out of the other conductor layers is desirably galvanically connected to the second conductor via 106 and is insulated from the first conductor plane 101 and a conductor layer used as a power plane out of the other conductor layers. The structure 1 may further include holes, vias, signal lines, and the like, not depicted, as far as they do not contradict the configurations of the present invention.

In the present example embodiment, the clearances formed in the first conductor plane 101, the second conductor plane 102, the third conductor plane 103, and the first planar conductor 104 do not necessarily need to be hollow and may be filled with a dielectric inside. In other words, the first conductor via 105 may pass through a dielectric that fills the clearances and may be formed in such a way that the first conductor via 105 does not contact the second conductor plane 102 and the third conductor plane 103. Similarly, the second conductor via 106 may pass through a dielectric that fills the clearances and may be formed in such a way that the second conductor via 106 does not contact the first conductor plane 101 and the first planar conductor 104.

In the present example embodiment, the structure 1 may be a structure group that includes a plurality of structures 1.

In this case, adjacent first conductor planes 101 are connected with each other. Second conductor planes 102 and third conductor planes 103 are configured in a similar manner. A plurality of first planar conductors 104 are arranged like islands spaced apart from adjacent first planar conductors 104.

FIG. 4 is a configuration diagram illustrating a configuration of a wiring substrate 10 according to the first example embodiment. FIG. 4(A) illustrates a top view of the wiring substrate 10 (here, a first conductor plane 101 is omitted) and FIG. 4(B) illustrates an A-A′ cross-sectional view of the wiring substrate 10.

The wiring substrate 10 includes at least a layer K 11, a layer L 12, a layer M 13, and a layer N 14 and further includes at least one structure 1 described above. The wiring substrate 10 illustrated in FIG. 4 is configured by repeatedly arranging a plurality of structures 1 and includes a dielectric layer between the layer K 11 and the layer L 12, between the layer L 12 and the layer M 13, and between the layer M 13 and the layer N 14. In other words, the wiring substrate 10 illustrated in FIG. 4 includes a plurality of unit structures each of which is made up of a first planar conductor 104, a first conductor via 105, and a second conductor via 106 in the structure 1 described above.

In the case where the wiring substrate 10 includes a plurality of structures 1, adjacent first conductor planes 101 are connected with each other. Similarly, adjacent second conductor planes 102 are connected with each other and adjacent third conductor planes 103 are connected with each other.

In the case where the wiring substrate 10 includes a plurality of structures 1, a plurality of first planar conductors 104 are arranged like islands spaced apart from adjacent first planar conductors 104 in the wiring substrate 10. While hollow gaps are provided between adjacent first planar conductors 104 in FIG. 4, the gaps may be filled with a dielectric.

Since the wiring substrate 10 according to the present example embodiment includes the structure(s) 1, propagation of electromagnetic noise in a predetermined frequency band can be suppressed without changing design of an existing EBG structure in the case where the existing EBG structure is applied to a multilayer substrate (i.e., in the case where the third conductor plane 103 that is a GND plane is further provided in the existing EBG).

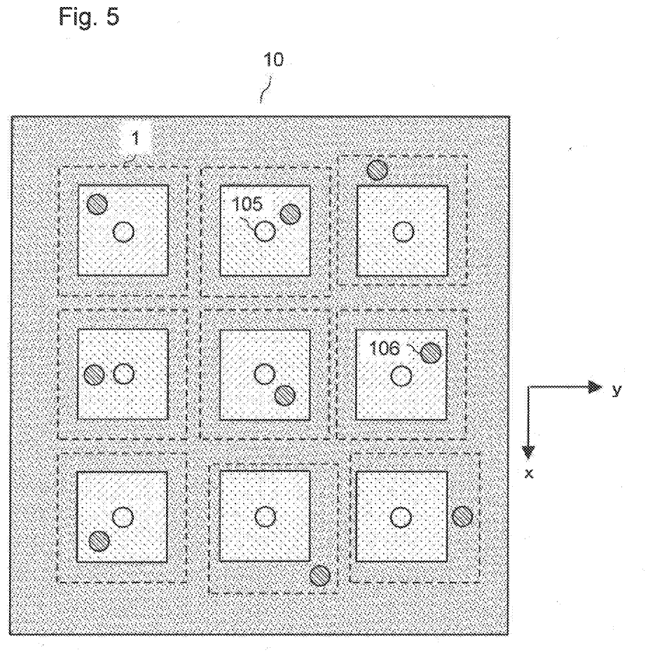

FIG. 5 is a top view illustrating a configuration of a variation of the wiring substrate 10 according to the first example embodiment. Here, first conductor planes 101 are omitted.

The wiring substrate 10 according to the present example embodiment is configured by arranging a plurality of structures 1 of an identical type as illustrated in FIG. 4. However, the wiring substrate 10 may be configured by arranging structures 1 of a plurality of types or may be configured by arranging structures 1 of an identical type with 105 and 106 provided in different directions as illustrated in FIG. 5.

In each of the structures 1 illustrated in FIGS. 1 to 5, the area of the planar conductor 104 plays an important role in defining an operating frequency of an EBG structure.

### Operating Principle of First Example Embodiment

A basic operating principle of a structure 1 according to the first example embodiment will be described below.

An operating principle of an existing EBG structure which does not include a third conductor plane 103 and a second conductor via 106 will be described first.

The EBG structure is made up of a first conductor plane 101, a second conductor plane 102, a first planar conductor 104, and a first conductor via 105. The first planar conductor 104 faces the second conductor plane 102 to form a capacitance. The first conductor via 105 which connects the first conductor plane 101 and the first planar conductor 104 together forms an inductance.

In other words, the EBG structure forms a resonant circuit in a form in which the first conductor plane 101 and the second conductor plane 102 are connected together. At a frequency in which impedance of the resonant circuit becomes inductive (the frequency will be herein referred to as design frequency), the first conductor plane 101, the second conductor plane 102, the first planar conductor 104, and the first conductor via 105 behave as an EBG structure (i.e., exhibit EBG characteristics). The EBG structure can forbid propagation of electromagnetic waves propagating through parallel plate wave guides formed by the first conductor plane 101 and the second conductor plane 102.

An operating principle of a structure 1 in which a third conductor plane 103 and a second conductor via 106 are added to the EBG structure descried above will be described next.

The structure 1 according to the first example embodiment includes a third conductor plane 103 and a second conductor via 106 in addition to the EBG structure described above (the first conductor plane 101, the second conductor plane 102, the first planar conductor 104, and the first conductor via 105). It is envisaged that the first conductor plane 101, the second conductor plane 102, and the third conductor plane 103 are power planes or GND planes in an actual electronic device. This configuration is often found in common electronic devices. However, in a structure that includes a plurality of power planes and GND planes like this, the presence of the third conductor plane 103 inhibits suppression of electromagnetic noise at the design frequency described above in spite of the provision of the EBG structure. In other words, EBG characteristics are no longer exhibited. This is because the first conductor plane 101 and the third conductor plane 103 are often galvanically connected together using a plurality of conductor vias, whereby a plurality of propagation paths are formed between the first conductor plane 101 and the third conductor plane 103.

To solve this problem, the second conductor via 106 is provided in the structure 1. The second conductor via 106 is provided near the first conductor via 105, i.e., near the resonant circuit formed by the first conductor via 105 and the first planar conductor 104. The second conductor via 106 serves to make the second conductor plane 102 and the third conductor plane 103 approximately equipotential by galvanically connecting the second conductor plane 102 and the third conductor plane 103 together near the resonant circuit. As a result, in spite of the presence of the third conductor plane 103 in the structure 1, the second conductor plane 102 and the third conductor plane 103 can be considered to be galvanically equivalent. Accordingly, the structure 1 exhibits EBG characteristics at the design frequency.

### Variations of First Example Embodiment

Variations of the first example embodiment will be described below.

A variation relating to the shape of the first planar conductor 104 will be described as a first variation.

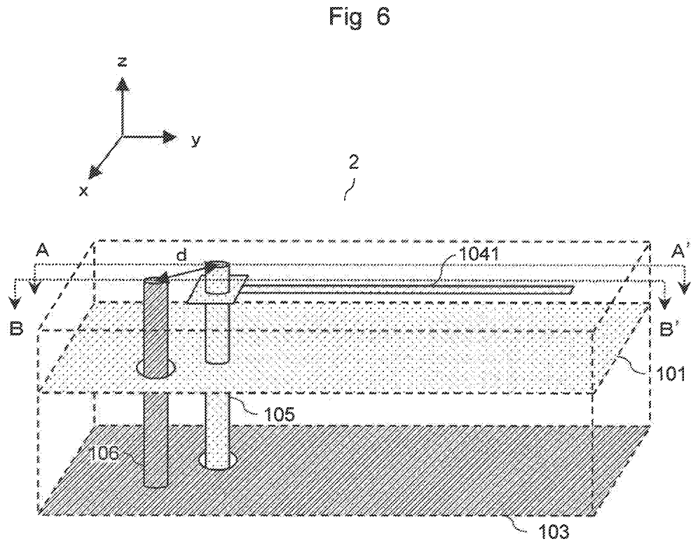

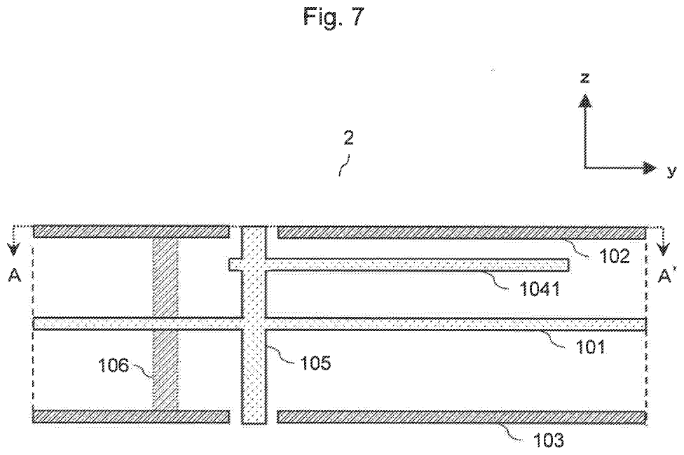

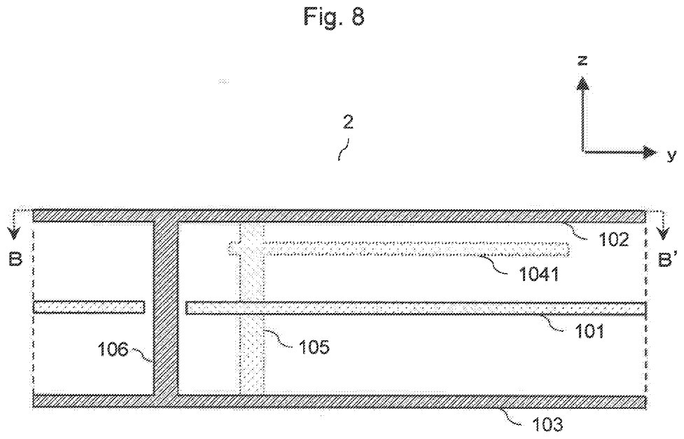

FIG. 6 is a perspective view illustrating a configuration of a variation of the structure 1 according to the first example embodiment of the present invention (here, a second conductor plane 102 is omitted). FIG. 7 is a A-A′ cross-sectional view of a structure 2 illustrated in FIG. 6. FIG. 8 is a B-B′ cross-sectional view of the structure 2 illustrated in FIG. 6.

In the first variation, the first planar conductor 104 is configured by a first transmission line 1041 as illustrated in FIG. 6. In the present variation, a first conductor via 105 is provided at an end of the first transmission line 1041 in order to cause the first transmission line 1041 to operate as a transmission line.

The length of the first transmission line 1041 (i.e., the length from the contact point between the first transmission line 1041 and the first conductor via 105 to one of the ends of the first transmission line 1041 that is farther from the first conductor via 105) is desirably equal to or greater than (λg/4−λg/16), where λg is a guide wavelength. In this configuration, the first transmission line 1041 behaves as a transmission line having an open end.

Impedance between the connection point between the first transmission line 1041 and the first conductor via 105, and the second conductor plane 102 is defined by input impedance of the open-end transmission line. The input impedance of the open-end transmission line is defined by characteristic impedance, a phase constant, and transmission line length of the transmission line. Especially the transmission line length plays an important role in determination of behavior.

In the present variation, an operating frequency of the EBG structure is determined by the length of the first transmission line 1041. Specifically, at a frequency near the frequency in which the guide wavelength λg becomes λg/4 of the first transmission line, inductive input impedance starts to appear and EBG characteristics on the lowest frequency side is exhibited.

In the present variation, the second conductor via 106 may be provided at a distance equal to or less than twice the length of the first transmission line 1041, more desirably equal to or less than the length of the first transmission line 1041, from the first conductor via in planar view (as viewed from the z-axis direction of a coordinate system in FIG. 6).

When an elongated first transmission line 1041 is adopted as the first plane conductor 104 as in FIG. 6, the operating frequency of the EBG structure is defined by the length of the first transmission line 1041. Therefore, the structure 2 according to the present variation allows the area of the first planar conductor 104 to be reduced as compared with the structures 1 illustrated in FIGS. 1 to 5 by reducing the transmission line width of the first transmission line 1041 (the length along the x-axis of the coordinate system in FIG. 6). In other words, the structure 2 can be implemented in a small size.

Another variation relating to the shape of the first planar conductor 104 will be described as a second variation.

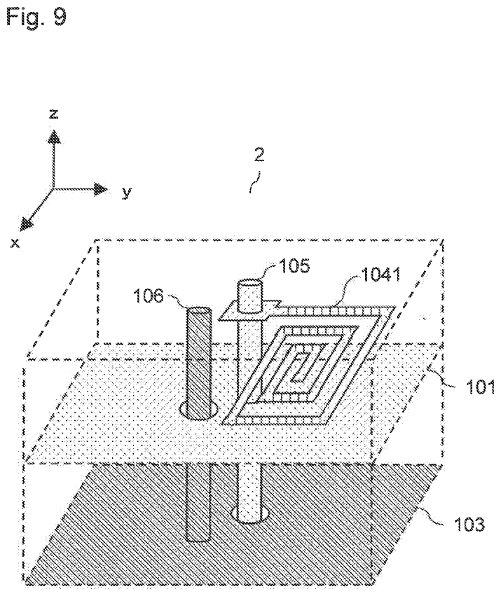

FIG. 9 is a perspective view illustrating a configuration of a variation of the first structure 1 according to the first example embodiment of the present invention (here, the second conductor plane 102 is omitted). A difference from the first variation is that the first transmission line 1041 has a spiral shape instead of a linear shape.

While the first transmission line 1041 has a spiral shape in the present variation, the first transmission line 1041 may have another shape, provided that the first conductor via 105 is connected at an end of the first transmission line 1041. For example, the first transmission line 1041 may have a shape such as a meander shape, a zigzag shape, or an irregular shape.

In the case where a variation of an existing EBG structure is applied to a multilayer substrate (i.e., in the case where the third conductor plane 103 that is a GND plane is further provided in an EBG structure made up of the first conductor plane 101 that is a power plane, the second conductor plane 102 that is a GND plane, the first transmission line 1041, and the first conductor via 105), the structure 2 of the present variation can suppress propagation of electromagnetic noise in a predetermined frequency band without changing design of the EBG structure.

By making the first transmission line 1041 into a spiral shape as illustrated in FIG. 9, the transmission line length in the present variation can be provided in a small mounting area. In other words, the structure 2 according to the present variation allows an EBG structure to be efficiently disposed in a small area.

By making the first transmission line 1041 into an irregular shape, the structure 2 according to the present variation allows the first transmission line 1041 to be wired in such a way as to avoid other constructions and the like. In other words, the structure 2 according to the present variation allows an EBG structure to be efficiently disposed in a limited area.

### Second Example Embodiment

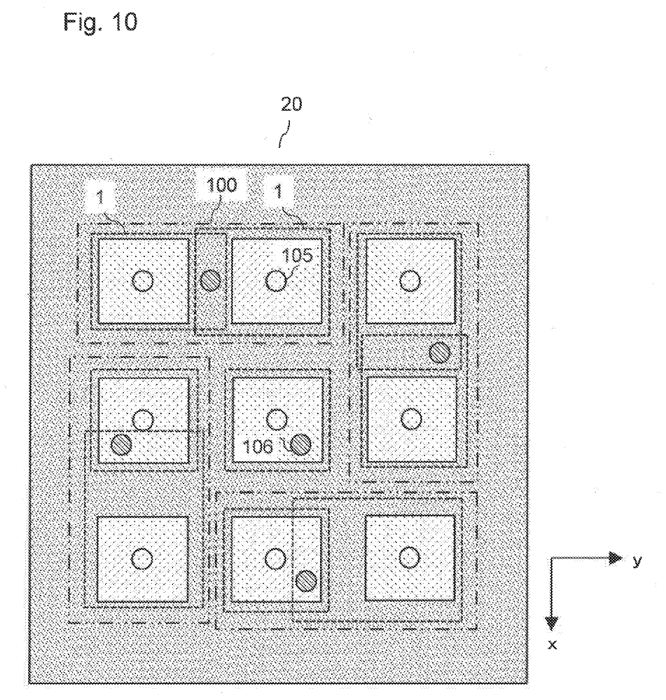

FIG. 10 is a top view illustrating a configuration of a wiring substrate 20 according to a second example embodiment of the present invention (here, a second conductor plane 102 is omitted). The wiring substrate 20 is a variation of the wiring substrate 10 according to the first example embodiment of the present invention.

Referring to FIG. 10, the wiring substrate 20 includes a plurality of structures 1. The wiring substrate 20 according to the second example embodiment differs from the wiring substrate 10 according to the first example embodiment in the following respect. The wiring substrate 20 according to the second example embodiment is configured by including one or more structure groups 100, each of which is made up of a plurality of structures 1.

Components that are provided in the wiring substrate 20 according to the second example embodiment 2 will be described below. However, description of configurations that overlaps with those of the first example embodiment will be omitted.

Structures 1 included in the structure group(s) 100 share a second conductor via 106 with each other.

Specifically, each structure group 100 is configured by including a plurality of EBG structures and one second conductor via 106. The structure group 100 includes the second conductor via 106 in a region in which a plurality of structures 1 overlap. The structure group 100 is configured in such a way that the distance d between each of a plurality of first conductor vias 105 and the second conductor via 106 is equal to or less than λg/2 (more desirably λg/4).

In the second example embodiment, the wiring substrate 20 can suppress propagation of electromagnetic noise generated between conductor planes because of the provision of the plurality of structures 1. The wiring substrate 20 exhibits EBG characteristics at a design frequency because of the provision of a second vias 106. Further, the wiring substrate 20 according to the second embodiment makes it possible to reduce the number of second conductor vias 106 used because a second conductor via 106 is shared among a plurality of structures 1. In other words, the wiring substrate 20 according to the second example embodiment can be implemented efficiently and in a space-saving manner.

### Third Example Embodiment

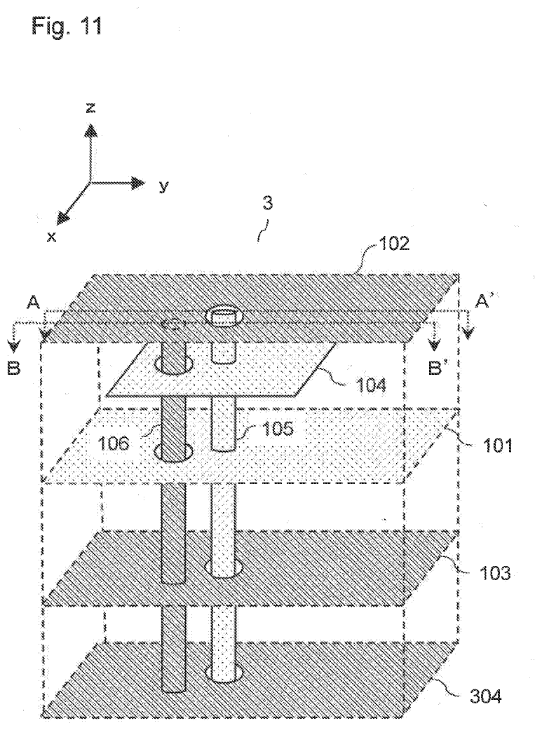

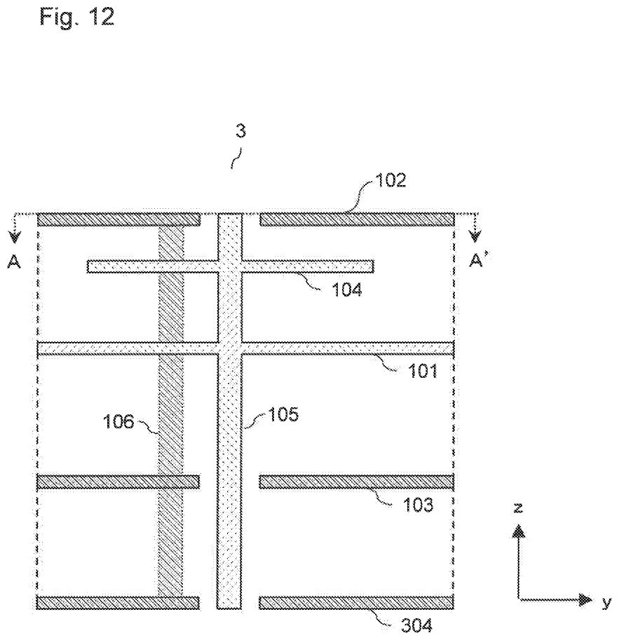

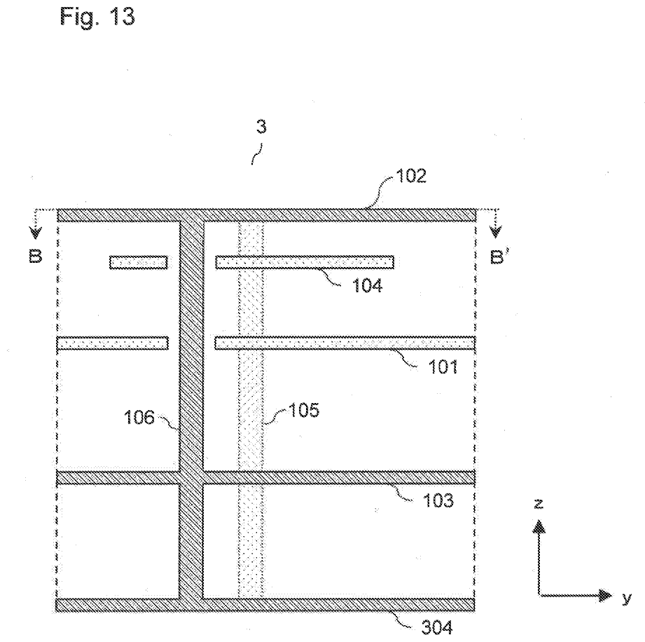

FIG. 11 is a perspective view illustrating a configuration of a structure 3 according to a third example embodiment of the present invention. FIG. 12 is an A-A′ cross-sectional view of the structure 3 illustrated in FIG. 11. FIG. 13 is a B-B′ cross-sectional of the structure 3 illustrated in FIG. 11. The structure 3 is a variation of the structure 1 according to the first example embodiment of the present invention.

Referring to FIG. 11, the structure 3 differs from the structure 3 according to the first example embodiment in that the structure 3 further includes a fourth conductor plane 304 in addition to the configuration of the structure 1.

Components provided in the structure 3 according to the third example embodiment will be described below. However, description of configurations that overlaps with those of the first example embodiment will be omitted.

The fourth conductor plane 304 is a flat plate that extends in a plane parallel to an xy plane of a coordinate system illustrated in FIG. 11 and faces a second conductor plane 102 or a third conductor plane 103. In the case where the fourth conductor plane 304 faces the second conductor plane 102, the fourth conductor plane faces the surface opposite to the surface of the second conductor plane 102 that faces a first planar conductor 104. In the case where the fourth conductor plane 304 faces the third conductor plane 103, the fourth conductor plane 304 faces the surface opposite to the surface of the third conductor plane 103 that faces the first conductor plane 101. In other words, the fourth conductor plane 304 is formed in a layer different from the other conductor planes 101 to 103 and the first planar conductor 104. It is envisaged that the fourth conductor plane 304 is a GND plane in an actual electronic device. In this case, the fourth conductor plane 304 is galvanically connected to the second conductor plane and the third conductor plane 103 through a second conductor via 106.

In the present example embodiment, the structure 3 can suppress electromagnetic noise in a predetermined frequency band without changing design of an existing EBG structure even in a multilayer substrate that has a larger number of layers.

### Fourth Example Embodiment

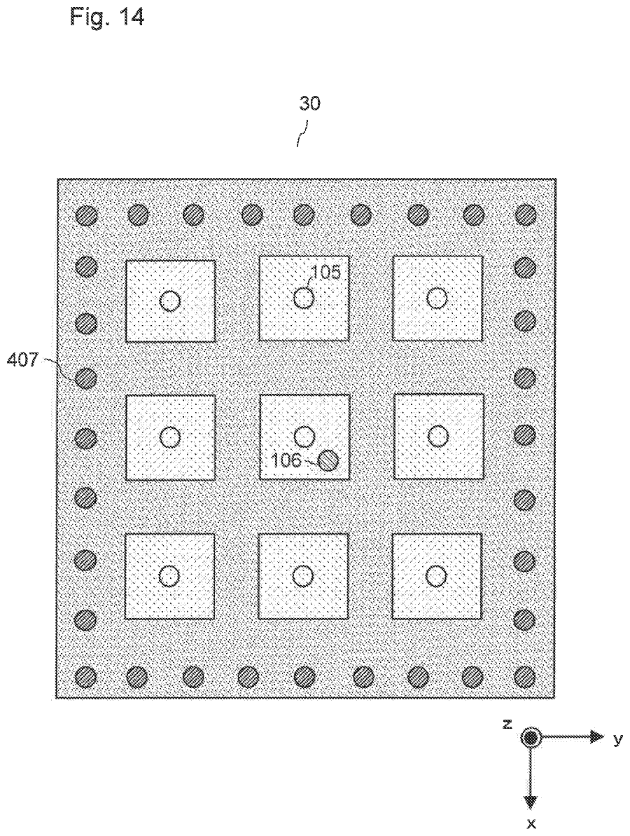

FIG. 14 is a top view illustrating a configuration of a wiring substrate 30 according to a fourth example embodiment of the present invention (here, a second conductor plane 102 is omitted). The wiring substrate 30 is a variation of the wiring substrate 20 according to the second example embodiment of the present invention.

Referring to FIG. 14, the wiring substrate 30 includes a plurality of EBG structures, at least one second conductor via 106 and a plurality of GND vias 407. The wiring substrate 30 according to the fourth example embodiment differs from the wiring substrate 10 according to the first example embodiment in the following respect. The wiring substrate 30 according to the fourth example embodiment includes the plurality of GND vias 407 in such a way that the plurality of GND vias 407 surround the plurality of EBG structures and includes a second conductor via 106 near the center of the plurality of EBG structures.

Components provided in the wiring substrate 30 according to the fourth example embodiment will be described below. However, description of configurations that overlaps with those of the first example embodiment will be omitted.

The plurality of GND vias 407 extend in the z-axis direction of a coordinate system illustrated in FIG. 14 and galvanically connects a second conductor plane 102 and a third conductor plane 103 together. The plurality of GND vias 407 are disposed in such a way as to surround the plurality of EBG structures.

One second conductor via 106 is provided near the center of the plurality of EBG structures.

In the case where the distance between a first conductor via 105 constituting each EBG structure and any of one second conductor via 106 and the plurality of GND vias 407 that is located closest to the first conductor via 105 is not equal to or less than λg/2 (more desirably λg/4), another second conductor via 106 may be further provided near that first conductor via 105.

In the fourth example embodiment, since the wiring substrate 30 includes a plurality of GND vias 407 and the second conductor via 106, the wiring substrate 30 can suppress electromagnetic noise generated between conductor planes. In addition, the wiring substrate 30 according to the fourth example embodiment makes it possible to further reduce the number of second conductor vias 106 used because the GND vias 407 are provided around the EBG structures. In other words, the wiring substrate 30 according to the fourth example embodiment can be more efficiently implemented because complicated wirings which require clearances are reduced.

While the present invention has been described with reference to example embodiments and variations, the present invention is not limited to the example embodiments described above. Various combinations and modifications of configurations and details of the present invention that can be understood by those skilled in the art are possible within the scope of the present invention.

This application is based upon and claims the benefit of priority from the Japanese Patent Application No. 2016-094958 filed on May 11, 2016, the entire disclosure of which is incorporated herein.

### INDUSTRIAL APPLICABILITY

Example applications of the present invention include a structure, a wiring substrate and the like that can suppress electromagnetic noise in a predetermined frequency band in a multilayer substrate including a plurality of pairs of a power plane and a GND plane.

### REFERENCE SIGNS LIST

1, 2, 3 Structure
10, 20, 30 Wiring substrate
101 First conductor plane
102 Second conductor plane
103 Third conductor plane
104 First planar conductor
105 First conductor via
106 Second conductor via
1041 First transmission line
100 Structure group
304 Fourth conductor plane
407 GND via

What is claimed is:

1. A structure comprising:
a first conductor plane that is a power source plane;
a second conductor plane that is a GND plane and faces the first conductor plane;
a third conductor plane that is a GND plane and faces the first conductor plane or the second conductor plane;
a first planar conductor that faces at least one of the second conductor plane and the third conductor plane;
a first conductor via that connects the first planar conductor and the first conductor plane, and is insulated from the second conductor plane and the third conductor plane; and
a second conductor via that connects the second conductor plane and the third conductor plane, and is insulated from the first conductor plane and the first planar conductor.

2. The structure according to claim 1, wherein
the second conductor via is disposed at a distance equal to or less than λg/2 from the first conductor via, where λg is a guide wavelength at an operating frequency.

3. The structure according to claim 1, wherein
the first planar conductor is a transmission line; and
the first conductor via is provided at an end of the transmission line.

4. The structure according to claim 3, wherein
the second conductor via is provided at a distance, from the first conductor via in planar view, that is equal to or less than twice a length of the transmission line.

5. The structure according to claim 1, further comprising a plurality of unit structures each of which is constituted of the first planar conductor, the first conductor via, and the second conductor via.

6. The structure according to claim 5, wherein
at least two of the plurality of unit structures share a second conductor via with each other.

7. The structure according to claim 1, further comprising a fourth conductor plane that is a GND plane and faces at least one of the first to third conductor planes, wherein
the second conductor via connects the second conductor plane, the third conductor plane, and the fourth conductor plane, and is insulated from the first conductor plane and the first planar conductor.

8. A structure comprising:
a first conductor plane that is a power source plane;
a second conductor plane that is a GND plane and faces the first conductor plane;
a third conductor plane that is a GND plane and faces the first conductor plane or the second conductor plane;
a plurality of first planar conductors that face at least one of the second conductor plane and the third conductor plane;
a plurality of first conductor vias that connect each of the plurality of first planar conductors and the first conductor plane, and are insulated from the second conductor plane and the third conductor plane;
a plurality of GND vias that are provided in such a way as to surround the plurality of first planar conductors in planar view, and connect the second conductor plane and the third conductor plane; and
at least one second conductor via near a center of a region in which the plurality of first planar conductors are provided, connects the second conductor plane and the third conductor plane, and is insulated from the first conductor plane and the plurality of first planar conductors.

9. A wiring substrate comprising the structure according to claim 1.

10. A wiring substrate comprising the structure according to claim 8.
